(19) United States
(12) Patent Application Publication
(10) Pub. No.: US 2006/0124915 A1
(43) Pub. Date: Jun. 15, 2006

(54) Production of an optoelectronic component that is enclosed in plastic, and corresponding methods

(76) Inventors: Siegfried Buettner, Erfurt (DE); Roy Knechtel, Geraberg (DE)

Correspondence Address: DUANE MORRIS LLP;IP DEPARTMENT, 30 SOUTH 17TH STREET, PHILADELPHIA, PA, 19103-4196, US

(21) Appl. No.: 10/556,980

(22) PCT Filed: May 19, 2004
(86) PCT No.: PCT/DE04/01045

§ 371 Date: Feb. 2, 2006

(30) Foreign Application Priority Data
May 19, 2003 (DE) 103 22 751.2

(51) Int. Cl. H01L 47/00

(52) U.S. Cl. 257/4

(57) ABSTRACT

The invention relates to a simplified method for assembling optoelectronic components that are enclosed in plastic and the construction thereof. The individual component unit contains a semiconductor chip (11) and an optical window (10). A hermetic inclusion of at least the optically active of the semiconductor chip via the window ensues in the wafer-slicing process, i.e. before separation. A (window) wafer provided with recesses (7) and occupied, in areas, by a joining layer is joined to the pre-prepared semiconductor wafer (1) via the joining layer that seals the optically active areas. Before separation, the contact areas and the separating areas of the separation are exposed by a severing (8) that is precise with regard to the recesses. An inspection measuring of the component units can ensue when the wafers are joined.

The invention relates to a method for the production of an optoelectronic component consisting of a semiconductor chip and an optical window that is transparent to a specific wavelength range and that is placed on it, which are enclosed in plastic as a compact component unit. The method comprises in particular the providing of the optical window in a sheet¹ composite and the exposing of the separating areas of the singling and the areas of contact of the semiconductor element, which is connected therewith, for the electrical contacting for the purpose of a control measurement prior to the encapsulation.
¹ translator's note: the term “Scheibe” in German has two meanings in English, i.e. “sheet” and “wafer”.

Electrooptical semiconductor components have been used for the conversion of electrical to optical signals and vice versa for quite a long time. Due to integrated circuits, the signals can also be immediately further processed. The actual optical semiconductor element must be enclosed in a protective housing for the electric contacting and the mechanical fixing in the optical path and for protection against environmental influences, which has an optical window that is transparent for the respective radiation. Special materials and methods are known for encapsulating the optical semiconductor elements in transparent housings. The providing of an optical window on the chips according to DE 43 19 786 A1 or its inclusion in the housing, cf. U.S. Pat. No. 6,117,705, DE 41 35 189 A1 is connected with considerable expenditure and high costs.

The general state of the production technology is disclosed in DE 43 19 786 A1.

Here, it is essential that the semiconductor wafer is first of all singled and then the covering with a glass window is implemented. This is subject to two different kinds of disadvantages. On the one hand, there is the risk of pollution of the semiconductor circuit during singling and, on the other hand, it is relative expensive to individually provide the chips with glass windows. Auxiliary devices for the positioned insertion of the glass windows are required and adjustment errors may occur.

The succession of a few essential main operations for producing the individual component unit corresponds roughly to the following sequence of steps:

1—singling of the semiconductor wafer

2—bonding of the chips on the carrier by means of an adhesive

3—curing of the adhesive

4—applying the adhesive on the glass window

5—providing the glass window

6—curing of the adhesive

7—wire bottom of the connections

8—enclosing of the unit by means of injection molding

Due to the individual processing when connecting the semiconductor chip with the glass window, the time expenditure is relatively great and the entire method cannot be universally used.

The invention is based on the object of indicating a more rational production method which protects the optically active structures of the semiconductor chip against damage such as pollution in a phase that is as early as possible, saves working steps and can be used more universally.

The increase in the quality of the component units is achieved and assembly time and costs are saved.

According to the invention the object is achieved by the fact that, instead of the further processing of the separated component chips for the hermetic sealing with the optically transparent window, a collective processing is implemented in the semiconductor sheet composite by connecting an optically transparent sheet (window sheet) that corresponds to the size of the semiconductor wafer with the semiconductor wafer and then singling is carried out.

The invention i.a. also has the advantage that, during the further processing, the optically active area of the chip is already protected and that there can be no failures due to pollution and mechanical damage. The sheet is provided with a connecting layer, e.g. imprinted with a glass solder in predetermined areas. Then, a (groove-like) indenting of the sheet from the bottom side in predetermined areas is implemented, which are adapted to the size of the individual element disposed in the screen. After connection of the bottom side of the window sheet with the semiconductor wafer, the sheet is sliced from the upper side, which is implemented with a targeted accuracy as regards the recesses of the bottom side, which are provided for slicing.

The optically active surface of each chip remains hermetically enclosed, while the areas of contact of the chip and the separation areas of the singling are exposed.

It is within the framework of the inventive solution that, in addition, indentations can still be implemented in the larger sheet, which, later on, form cavities above micromechanical structures, e.g. as a component of integrated circuits, in the hermetic sealing. After the optoelectronic control measurement that can be implemented in the sheet composite, singling is implemented. Then, with a corresponding thickness, the separated compact component unit can be used in standard lead-frame-based semiconductor housings and also in other assembly variants (COB and many more).

This process can be used for all chips with optically active structures.

A polishing of one or both surfaces of the large sheet improves the transmission behaviour. A plane-parallelism is achieved.

A rough marginal side (lateral) of the (already detached) window improves the stopping of the plastic material during casting. The surface of the smaller window remains securely clean.

The invention is to be explained in greater detail by means of examples of embodiments.

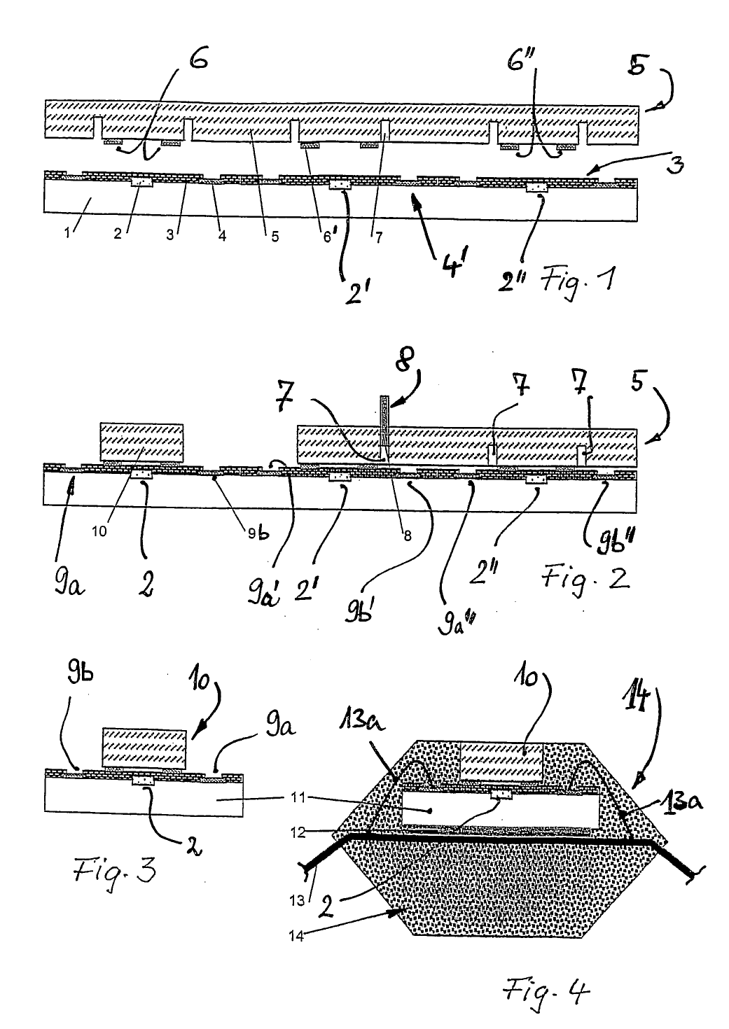

FIG. 1 schematically shows a cross-sectional view of two sheets to be connected, the upper one being the optical window that is transparent in the corresponding wavelength range and consists e.g. of glass. It comprises indentations and is locally provided with a connection layer;

FIG. 2 shows the two sheets of FIG. 1 in connected condition during the slicing of the wafer;

FIG. 3 is a component unit after singling;

FIG. 4 is the finished component enclosed in plastic.

The process for encapsulating optoelectronic semiconductor components comprises two partial complexes. One complex is the providing of the pre-prepared (window) sheet on the semiconductor wafer with the optically active areas 2 and other possible circuit structures and the connection of the two with each other. The other complex is the slicing of the optically transparent sheets in order to expose electrical contacts and the separation paths of the singling, the control measurement, the contacting and encasing of the individual elements with plastic, e.g. by means of injection molding.

According to FIG. 1 finished, processed semiconductor wafers 1 with optically sensitive elements 2 are the point of departure, whose surface is protected by a customary passivation 3, which only comprises openings in the area of the electric terminals 4, 4′.

The providing of the optical window 10 (cf. FIG. 2) as a component of the optical sheet 5 and the exposing of the areas of contacting 4 is implemented in the sheet composite, whereby, due to the parallel processing of a large number of elements, the expenditure and the unit costs can be kept small.

The providing of the windows is carried out by means of selective sheet bonding using a structured connection layer 6. For this purpose, the connection layer 6 is applied onto the optical sheet 5, which is transparent in the required wavelength range (e.g. glass). The structuring of the connection layer 6 can already be implemented during the providing or afterwards. The structure of the connection layer 6 must be adapted to the semiconductor component so that in each case a closed frame around a respective optically sensitive element is formed and a sufficient distance to optically sensitive elements and the areas of contacting 4, 4′ is ensured.

The indentations 7 of the sheet 5 are provided in the contact areas from the connection side, e.g. sawn. This is carried out prior to the bonding across the structured layer 6.

The sawing 7 of the sheet as a prerequisite of the later exposing of the areas of contacting 4 must be carried out observing the sheet thickness so that both the mechanical stability of the sheets is ensured and the semiconductor structures are not damaged during sawing after the connection of the sheets. After a corresponding alignment of semiconductor wafer 1 and window sheet (also sheet) 5, they are connected. “Sawing” means an optional type of severing (slicing).

The process management depends upon the type of the respectively used intermediate connection layer 6 observing minimum mechanical tensions in the connection plane. The connection has a high planarity between sheet 5 and semiconductor wafer 1, which is positive for the further processing.

After the connection of the sheets the total thickness of the stack of sheets can be adjusted by means of grinding. The exposure of the contact areas is implemented by sawing (8) in the area of the indentations 7 from the exposed, non-bonded side of the window sheet 5 in such a way that the two cuts superimpose (supplement) each other in their depth, and, due to this, the parts between the bonded areas forming a frame, which are not connected with the semiconductor wafer 1 (no bonded intermediate layer and/or opened intermediate layer structure) fall out.

The final electric control of the sheets can be implemented in this condition, during which failures caused by the processes during the providing of the windows can be recognized.

Subsequently, the semiconductor wafers can be sliced into individual elements 11 at the separation areas by means of standard processes, cf. FIG. 3. They are located outside the contact areas 4, 4′. The subsequent encapsulation of the individual elements can then be implemented analogously to the standard components.

The chips are individually attached to the metallic carrier strip 13 by means of adhesive 12. After the curing of the adhesive, a wire bonding 13a for a contacting between chip and carrier strip is implemented (outer terminals).

The actual surrounding housing is e.g. formed by means of plastic injection molding, by injecting softened plastic material 14 using a mold around the arrangement of chip and carrier strip. During this process the lateral faces of the glass top 10 (optical window) represent a block for the plastic material, whereby it is ensured that no casting material gets onto the optical window and soils it. The optical window is embedded in the surface of the housing.

A simplified process for the assembly of optoelectronic components encased in plastic material and their structure are described. The individual component unit contains a semiconductor chip (11) and an optical window (10). A hermetic inclusion of at least the optically active areas of the semiconductor chip by means of the window is already implemented in the sheet process, i.e. prior to singling. A (window) sheet provided with indentations (7) and locally coated with a connection layer is connected with the pre-prepared semiconductor wafer (1) by means of the connecting layer sealing the optically active areas. Prior to singling, the contact areas and the separation areas of the singling are exposed by means of a slicing of the window sheet (8) that is targeted as regards the indentations. A control measurement of the component units can be implemented in the sheet composite.

### LIST OF REFERENCE NUMERALS

1: semiconductor wafer with optically sensitive structures 2, 2′, 2″, which may also be a component of complex electronic circuits
2: optically active structure
3: passivation layer
4: contact area, also 4′
5: optically transparent sheet
6: structured connection layer (intermediate bond layer)
7: indentations (e.g. sawing cut)
8: saw blade
9: exposed contact area, also 9a, 9b; 9a′, 9b′; 9a″, 9b″
10: optical window
11: singled chip
12: adhesive
13: carrier strip
14: plastic material (plastic housing)

We claim:

1. A process for the production of an optoelectronic component enclosed in plastic and consisting of a semiconductor chip with optically active structures, which may also be present in connection with integrated circuits and an optically transparent window (10) located above it, the optically sensitive part (1) being hermetically sealed against the outer atmosphere by the optical window, which comprises the following production steps:
(a) preparing a plane-parallel sheet that is optically transparent in the relevant wavelength range and adapted to the size of the semiconductor wafer by
(A) making of indentations which are adapted to the element size of the semiconductor chips as regards their dimensions and arrangements in the bottom side of the sheet which is to be connected later on, which serve for the later exposing of the contact areas and separation paths when singling the chips, and
(B) applying a connection layer onto the bottom side of the sheet in such a structured manner that, after the subsequent connection, it spares the area of the optically active structure and encloses it in an annular fashion, but spares it and the subsequent contact areas and separation paths of singling; and/or
(b) connecting the sheet of optically transparent material with the semiconductor wafer which contains the optically active structures and circuits in a finished condition by means of the connecting layer with the aid of adjusting means for the mutual alignment/covering of the structures present on both sheets; and/or
(c) slicing (8) of the optically transparent sheet from the upper side by means of a processing in those areas in which this sheet comprises indentations (7) on the bottom side for the purpose of slicing; and/or
(d) eliminating the separated parts of the optically transparent sheet above the contact areas and the separating traces of the semiconductor wafer; and/or
(e) control measurements of the individual elements by means of terminals of the contacts in the contact areas; and/or
(f) singling of the semiconductor wafer; and/or
(g) further processing (in a known fashion) by means of providing the component unit on a carrier (13), wire bonding for the production of the outer terminals (13a) and enclosing of the component unit with plastic (14).

2. The process for the production of an optoelectronic component enclosed in plastic according to claim 1, wherein the making of the indentations and the providing of the connection layer is implemented in the reverse order with respect to the optically transparent sheet.

3. The process for the production of an optoelectronic component enclosed in plastic according to claim 1, wherein the making of the indentations (7) of the optically transparent sheet is carried out by means of cutting off by grinding.

4. The process for the production of an optoelectronic component enclosed in plastic according to claim 1, wherein the making of the indentations of the optically transparent disk is carried out by means of etching.

5. The process for the production of an optoelectronic component enclosed in plastic according to claim 1, wherein the providing of the connection layer (6) on the optically transparent sheet (5) is implemented homogeneously and then the structuring is carried out.

6. The process for the production of an optoelectronic component enclosed in plastic according to claim 1, wherein the providing of the connection layer on the optically transparent sheet is carried out in a structured fashion, e.g. by means of printing.

7. The process for the production of an optoelectronic component enclosed in plastic according to claim 1, wherein the optically transparent sheet (5) consists of quartz.

8. The process for the production of an optoelectronic component enclosed in plastic according to claim 1, wherein the optically transparent sheet consists of glass.

9. The process for the production of an optoelectronic component enclosed in plastic according to claim 1, wherein the optically transparent sheet consists of a semiconductor material.

10. The process for the production of an optoelectronic component enclosed in plastic according to claim 1, wherein the connection of the two sheets is carried out by means of sheet bonding.

11. The process for the production of an optoelectronic component enclosed in plastic according to claim 1, wherein the connection of the two sheets is carried out by means of a glass solder.

12. The process for the production of an optoelectronic component enclosed in plastic according to claim 1, wherein the connection of the two sheets is carried out by means of a plastic material.

13. The process for the production of an optoelectronic component enclosed in plastic according to claim 1, wherein the slicing of the optically transparent sheet is carried out by means of cutting off by grinding.

14. The process for the production of an optoelectronic component enclosed in plastic according to claim 1, wherein the slicing of the optically transparent sheet is implemented by means of laser irradiation.

15. The process for the production of an optoelectronic component enclosed in plastic according to claim 1, wherein, upon the sealing of the component unit, in which the optical window (10) is embedded in the surface of the plastic housing, with plastic, the lateral faces of the optical window are used for stopping the plastic injection molding composition.

16. An optoelectronic component, enclosed in plastic and producible according to a process according to claim 1 and one or several of the dependant claims.

17. A process for producing one or several electronic components that are sealed and/or enclosed in plastic from a semiconductor chip (11) with at least one optically active structure (2) and an optically transparent window (10) that is affixed above it by means of a structured connection layer (6) and that hermetically seals the optically active structure (2),
wherein the semiconductor chip (11) is affixed on a metallic carrier strip (13) by means of an adhesive (12);
wherein, upon the sealing in plastic, the optical window is embedded in the surface of the plastic housing and the lateral faces of the optically transparent window (10) stop the spreading of the plastic material (14);
wherein, prior to the sealing with plastic to form a “plastic sealing”, an optical sheet (5) which is larger than the optical window (10) is connected (6) with several semiconductor chips (11) in a semiconductor wafer (1), the optical sheet (5) has indentations (7) on its bottom side that is the connection side to the semiconductor wafer (1);
after the connection, the optical sheet (5) is sliced or separated from its upper side until at least several of the indentations (7) are reached;
wherein at least one section of the optical sheet (5) is sliced or separated in order to expose at least one contact area (4) for the electrical contacting and at least one separation area for singling.

18. The process according to claim 17, wherein the slicing, severing or separating is implemented by means of sawing.

19. The process according to claim 17, wherein the slicing (8) is carried out up to the depth of the indentations (7) which must be separated and the respective separation point is above the respective indentation.

20. The process according to claim 1 or claim 17, wherein the lateral end faces of the window (1) are roughened.

21. The process according to claim 1 or claim 17, wherein at least one surface of the sheet (10) is polished in particular as a plane-parallel sheet.
